(19) United States
(12) Patent Application Publication
(10) Pub. No.: US 2026/0088937 A1
(43) Pub. Date: Mar. 26, 2026

(54) COMMUNICATION DEVICES AND METHODS

(71) Applicant: Sony Group Corporation, Tokyo (JP)

(72) Inventors: Pukar SHAKYA, Stuttgart (DE); Thomas HANDTE, Stuttgart (DE); Daniel VERENZUELA, Stuttgart (DE); Ken TANAKA, Stuttgart (DE)

(73) Assignee: Sony Group Corporation, Tokyo (JP)

(21) Appl. No.: 19/110,108

(22) PCT Filed: Sep. 12, 2023
(86) PCT No.: PCT/EP2023/075043

§ 371 Date: Mar. 10, 2025

(30) Foreign Application Priority Data
Sep. 19, 2022 (EP) 22196324.2

(51) Int. Cl. H04L 1/1812; H03M 13/11; H04L 5/00

(52) U.S. Cl. CPC H04L 1/1812; H03M 13/1125; H04L 5/0053

(57) ABSTRACT

A first communication device is configured to communicate with a second communication device, the first communication device comprising circuitry configured to receive data units, a received data unit comprising an information part and at least a portion of a parity part of a codeword comprising said information part and said parity part, from the second communication device; provide an indication to the second communication device indicating at least one erroneous data unit that failed to be received or decoded by the first communication device: receive a retransmission of the erroneous data unit having an identical information part as the corresponding originally transmitted data unit: accumulate log-likelihood ratios (LLRs) of the erroneous data unit and the corresponding retransmission of the erroneous data unit; and decode the data unit based on the accumulated LLRs.

### BACKGROUND

### Field of the Disclosure

The present disclosure relates to first and second communication devices and methods, in particular for use in wireless LAN (WLAN) systems.

### Description of Related Art

WLAN features hybrid automatic repeat request (HARQ) type I which features a combination of forward error correction (FEC) and automatic repeat request (ARQ) protocol. Thereby, any MAC layer data unit to be transmitted is first supplied with a frame check sequence (FCS) and then encoded by a forward error correction encoder such as low-density parity-check (LDPC) code. Upon reception, the receiver (herein also called “first communication device”) performs FEC decoding and subsequently checks the validity of FCS. If the FCS is valid, the automatic repeat request (ARQ) mechanism transmits a positive acknowledgement (ACK) to the transmitter (herein also called “second communication device”) to indicate successful reception. If the FCS is invalid, the ARQ mechanism transmits a negative acknowledgement (N-ACK) or nothing to the transmitter to indicate that a retransmission of the MAC layer data unit is needed. After a certain number of retransmissions, e.g., depending on a lifetime of a data unit, the transmission was either successful or not, in which case the MAC layer data unit is discarded at the transmitter. Thus, in poor channel conditions where signal strength is weak, HARQ type I may fail to provide reliable communication because initial transmission and retransmissions may fail.

The “background” description provided herein is for the purpose of generally presenting the context of the disclosure. Work of the presently named inventor(s), to the extent it is described in this background section, as well as aspects of the description which may not otherwise qualify as prior art at the time of filing, are neither expressly nor impliedly admitted as prior art against the present disclosure.

### SUMMARY

It is an object to provide communication devices and methods that can increase the link reliability and robustness of the wireless communication and, hence, can increase the overall efficiency of the system. It is a further object to provide a corresponding computer program and a non-transitory computer-readable recording medium for implementing said methods.

According to an aspect there is provided a first communication device configured to communicate with a second communication device, the first communication device comprising circuitry configured to
receive data units, a received data unit comprising an information part and at least a portion of a parity part of a codeword comprising said information part and said parity part, from the second communication device;
provide an indication to the second communication device indicating at least one erroneous data unit that failed to be received or decoded by the first communication device;
receive a retransmission of the erroneous data unit having an identical information part as the corresponding originally transmitted data unit;
accumulate log-likelihood ratios (LLRs) of the erroneous data unit and the corresponding retransmission of the erroneous data unit; and
decode the data unit based on the accumulated LLRs.

According to a further aspect there is provided a second communication device configured to communicate with a first communication device, the second communication device comprising circuitry configured to
transmit data units, a transmitted data unit comprising an information part and at least a portion of a parity part, to the first communication device;
obtain an indication from the first communication device indicating at least one erroneous data unit that failed to be received or decoded by the first communication device; and
retransmit the erroneous data unit having at least an identical information part as the corresponding originally transmitted data unit.

According to still further aspects a computer program comprising program means for causing a computer to carry out the steps of the methods disclosed herein, when said computer program is carried out on a computer, as well as a non-transitory computer-readable recording medium that stores therein a computer program product, which, when executed by a processor, causes the methods disclosed herein to be performed are provided.

Embodiments are defined in the dependent claims. It shall be understood that the disclosed communication methods, the disclosed computer program and the disclosed computer-readable recording medium have similar and/or identical further embodiments as the claimed communication devices and as defined in the dependent claims and/or disclosed herein.

One of the aspects of the disclosure is to extract from an erroneous data unit, instead of discarding it, some relevant information that may help in decoding the data unit in successive retransmissions. Initial (original) transmission and one (or more) retransmission(s) may be combined so that, although initial transmission and retransmission(s) may fail, a combination of them may be successful. Soft combining may be one of the techniques to combine log-likelihood ratio (LLR) values of a failed data unit with a retransmitted data unit, which will help to decode it correctly. Different embodiments of soft combining are presented herein.

The foregoing paragraphs have been provided by way of general introduction and are not intended to limit the scope of the following claims. The described embodiments, together with further advantages, will be best understood by reference to the following detailed description taken in conjunction with the accompanying drawings.

### BRIEF DESCRIPTION OF THE DRAWING

A more complete appreciation of the disclosure and many of the attendant advantages thereof will be readily obtained as the same becomes better understood by reference to the following detailed description when considered in connection with the accompanying drawings, wherein:

FIG. 1 shows a diagram of a known communication scheme in WLAN.

FIG. 2 shows a diagram illustrating a known encoding and decoding scheme for WLAN for an LDPC code.

FIG. 3 shows a diagram of a PPDU and its relation to a MPDU and codeword(s).

FIG. 4 shows an embodiment of a MAC header of a MPDU.

FIG. 5 shows a VHT-SIG-B and service field relationship.

FIG. 6 shows a simplified diagram of systematic encoding the data field of a PPDU according to an embodiment of the present disclosure.

FIG. 7 shows a diagram an embodiment of Chase combining scheme according to the present disclosure for two retransmissions.

FIG. 8 shows a diagram illustrating more details of the transmitter side of an encoding and decoding scheme according to the present disclosure.

FIG. 9 shows a diagram illustrating an embodiment of an encoding and decoding scheme according to the present disclosure.

FIG. 10 shows a diagram illustrating an embodiment of the operation of an accumulate unit as used in the encoding and decoding scheme shown in FIG. 9.

FIG. 11 shows a simplified diagram of systematic encoding the data field of a PPDU according to another embodiment of the present disclosure.

FIG. 12 schematically illustrates an embodiment of the HARQ Type Ill combining scheme according to the present disclosure.

FIG. 13 shows a diagram illustrating another embodiment of an encoding and decoding scheme according to the present disclosure.

FIG. 14 shows a diagram illustrating an embodiment of the operation of a selection unit as used in the encoding and decoding scheme shown in FIG. 13.

FIG. 15 shows a diagram illustrating an embodiment of the operation of a selective accumulate unit as used in the encoding and decoding scheme shown in FIG. 13.

FIG. 16 shows a diagram illustrating another embodiment of an encoding and decoding scheme according to the present disclosure.

FIG. 17 shows a diagram of another embodiment of a PPDU and its relation to a MPDU according to the present disclosure.

FIG. 18 shows a diagram illustrating another embodiment of an encoding and decoding scheme according to the present disclosure.

### DETAILED DESCRIPTION OF THE EMBODIMENTS

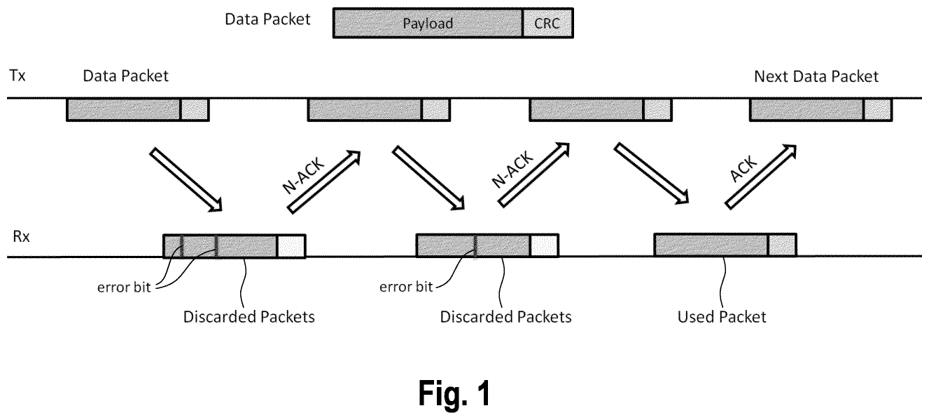

As mentioned above, WLAN features HARQ type I which features a combination of FEC and ARQ protocol as illustrated in FIG. 1 showing a diagram of a known communication scheme. Any MAC layer data unit to be transmitted is first supplied with a frame check sequence (FCS) and then encoded by a forward error correction encoder such as low-density parity-check (LDPC) code into a codeword (also called data unit) comprising an information part and a parity part. The data packet as shown in FIG. 1 is a MAC layer data unit that comprises a MAC header, user data and CRC bits. Typically, a MAC layer data unit is encoded into one or more data units (or codewords). The FCS contains CRC bits in order to detect if there is any bit error within the MAC layer data unit and the FEC encoder adds additional redundancy (parity bits) enabling the receiver to perform (bit) error correction. The bit error correction works on data unit or codeword basis.

The receiver performs FEC decoding of data units or codewords and subsequently checks the validity of FCS of the received MAC data unit. If the FCS is valid, the ARQ mechanism transmits a positive acknowledgement ACK to the transmitter to indicate successful reception. If the FCS is invalid, i.e., if there are bit errors as shown in the originally transmitted data unit and in the first retransmission, the ARQ mechanism transmits a negative acknowledgement N-ACK (or nothing, preferably after a timeout) to indicate that a retransmission of the MAC layer data unit is needed. After a certain number of retransmissions, e.g., depending on a lifetime of a MAC layer data unit, the transmission was either successful or not in which case the MAC layer data unit is discarded at the transmitter side.

It is important to note that in HARQ type I, an erroneous data unit, i.e. a MAC layer data unit with FCS invalid, is discarded by the receiver. Thus, the retransmission can be seen as separate from the initial transmission; hence, no combining of initial transmission and retransmission happens. There is hence no combination gain.

In WLAN, LDPC encoding is done based on the fixed block length or codeword (CW) (also called data unit herein) length, i.e., either 648, 1296 or 1944. The varying number of bits to be transmitted (e.g., because of different MAC layer data unit sizes and/or aggregated MAC layer data units) needs to be adapted to the codeword length for which reason an encoding and decoding scheme is preferred at transmitter or receiver, respectively.

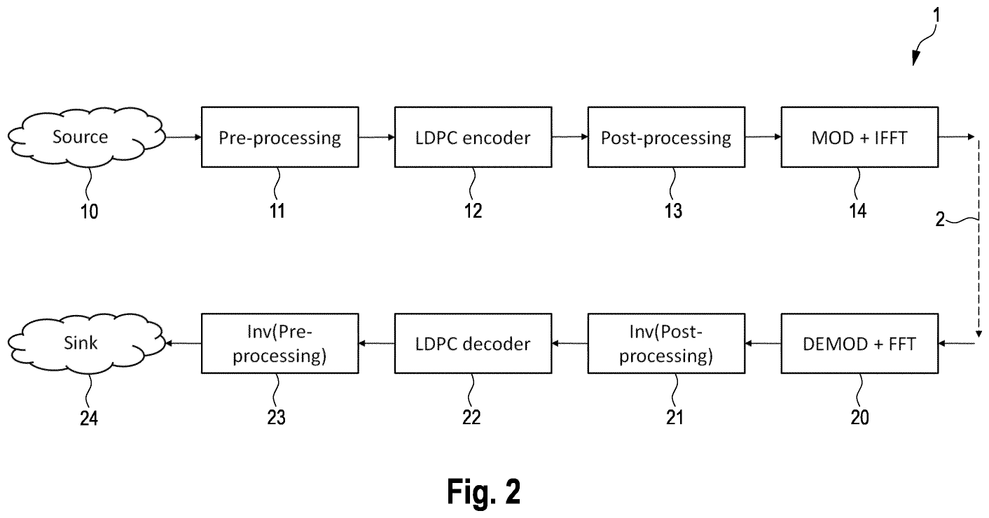

The encoding and decoding scheme 1 for WLAN is schematically shown in FIG. 2 for an LDPC code. The source provides the scrambled data of payload bits and FCS (CRC bits). These data are subsequently encoded and OFDM modulated to transmit over a wireless channel. LDPC codes operate with a codeword length. Therefore, when the user data has a variable size, pre- and post-processing is needed in order to fit the varying number of bits to one or more codewords. The LDPC encoding process in WLAN simultaneously fit the scrambled bits into a required minimum number of OFDM symbols and an integer number of codewords.

The pre-processing unit 11 determines the required minimum number of OFDM symbols (N_{SYM}) according to the total number of scrambled bits coming from the source 10. This unit also determines the codeword (CW) length (L_{LDPC}) and computes the number of codewords (N_{CW}) based on total number of scrambled bits. It shall be noted in this context that WLAN LDPC encoding offers three different code word size LDPC codes. They are selected depending on total number of scrambled bits. Typically, the largest code word size of 1944 bits is used, because a typical data unit length is 1500 bytes or 12000 bits. If the bits from the total number of scrambled data cannot fill the information part of N_{CW} codewords completely before encoding, then the required shortening bits (Nₛₕᵣₜ) are calculated. Shortening bits are bits of fixed value that are added to the information part of each codeword before the encoding, but which are discarded before transmission. The receiver includes those bits of fixed value before decoding. These shortened bits are not always possible to be equally distributed to the number of codewords. Hence, the first mod (Nₛₕᵣₜ, N_{CW}) codewords contain one more shortening bit than remaining codewords. The minimum number of shortening bits per codeword N_{spcw}=[Nₛₕᵣₜ/N_{CW}] are inserted.

The output of the pre-processing unit 11 is systematically encoded with the LPDC encoder 12 with the designated code rate (R) as per modulation and coding scheme (MCS) to obtain the codewords. In the post-processing unit 13, the inserted shortening bits in the information part of codewords are removed and either puncturing of the parity part of codewords (if the encoded bits are more than OFDM symbols can carry) or a repetition of the information part of codewords (if the encoded bits are less to fit the OFDM symbols) is performed. In a case where the total number of parity bits to be punctured to fit in OFDM symbols is too large, the coding performance will degrade. To avoid this, an extra OFDM symbol will be added if either of the following two conditions is met:
If the total number of punctured bits (N_{punc}) exceeds 30% of the total number of parity bits:

$${N}_{p u n c} > 0.3 * {N}_{CW} * {L}_{LDPC} * ( 1 - R ) ,$$

or
if the following two sub-conditions are true:

$${N}_{punc} > 0.1 * {N}_{CW} * {L}_{LDPC} * ( 1 - R ) AND$$

$${N}_{shrt} < 1.2 * {N}_{punc} * \frac{R}{1 - R} .$$

The output of post-processing unit 13 is then modulated as per MCS and undergoes IFFT in a modulation and IFFT unit 14 before it is transmitted over a wireless channel 2 as an OFDM signal. At the receiver, after FFT processing and demodulation in an FFT and demodulation unit 20, the inverse processes of the encoding procedure are carried out in an inverse post-processing unit 21, an LDPC decoder 22 and an inverse pre-processing unit 23 to retrieve the payload bits provided to the sink 24. The LDPC decoder 22, in WLAN, uses the belief propagation algorithm to decode a binary systematic LDPC code, whose input is the soft decision bitwise LLR values from a demodulator 20. The received signal, after passing through the demodulator 20, is sampled, and real values are measured for soft decision de-mapping. These real values are soft decision value of received bits for the corresponding bits in the M-ary modulated constellation points and are termed as bitwise log-likelihood ratio (LLR) values.

The maximum likelihood searches the constellation points with a higher probability to estimate LLR for each received bit in the received signal. Mathematically, LLR is the ratio of probabilities of a 0 bit being transmitted to the 1 bit being transmitted for a received signal and can be expressed as Eq. 1 where b is the transmitted bit (one of k bits in an M-ary symbol) and r is received signal with coordinates (x, y) in constellation diagram.

$$L ( b ) = log ( \frac{P r ( b = 0 \vert r = ( x , y ) )}{P r ( b = 1 \vert r = ( x , y ) )} ) \qquad ( 1 )$$

After applying Bayes rules and assuming all symbols are equally probable, the LLR value of code bit after passing a signal over additive white gaussian noise (AWGN) is expressed by Eq. 2 where S₀/S₁ is the constellations point with bit 0/1 at the given bit position, s_{κ}/s_{y} is the in-phase/quadrature coordinate of the constellation point, σ² is the noise variance of the baseband signal.

$$L ( b ) = log ( \frac{{\sum }_{s ϵ {S}_{0}} {e}^{- \frac{1}{{σ}^{2}} ( {( x - {s}_{x} )}^{2} + {( y - {s}_{y} )}^{2} )}}{{\sum }_{s ϵ {S}_{1}} {e}^{- \frac{1}{{σ}^{2}} ( {( x - {s}_{x} )}^{2} + {( y - {s}_{y} )}^{2} )}} ) \qquad ( 2 )$$

To summarize, an LLR value is a real number that indicates per bit the reliability of said bit. The more positive the value, the more likely a 0 bit was detected, whereas the more negative, the more likely a 1 bit was detected. A LLR value of zero means that both bits are equally probable.

In poor channel conditions where signal strength is weak, HARQ Type I fails to provide reliable communication, because initial transmission and retransmissions may fail. Discarding the failed data unit at the receiver leads to a waste of resources that have been used for the transmission. Hence, according to this disclosure, instead of discarding the erroneous data unit, it can be utilized to extract some relevant information that may help in decoding the data unit in successive retransmissions. In this regard, it is favorable to achieve a combination gain by combining initial transmission and one or more retransmission(s).

Assuming initial transmission and retransmission fail, ARQ will not achieve a successful data transfer but a combination of initial and retransmission may be successful that results in a valid FCS.

Soft combining is one of the techniques to combine log-likelihood ratio (LLR) values of failed data unit with a retransmitted data unit, which can help the decoder to decode it correctly. HARQ with soft combining can be done in two ways, i.e. Chase combining (CC) and Incremental Redundancy (IR). Both are categorized as HARQ Type II.

In the following, CC and HARQ Type III will be considered: In CC, the same information as the erroneous data unit will be retransmitted again, and LLR values of initial transmission and retransmissions will be combined at the receiver side. In HARQ Type III a combination of both CC and IR techniques is considered, in which, within the information part, LLR values are combined, but new parity information in retransmission is considered. The combination may be done on a one data unit or codeword basis. As a MAC layer data unit is often encoded in multiple data units or codewords, the combination process may repeat for all data units or codewords which contain the MAC layer data unit.

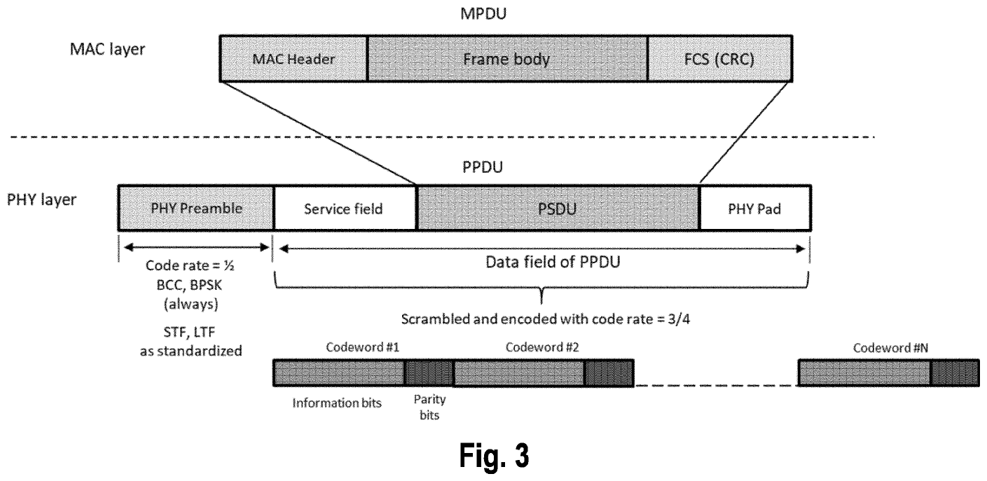

In the following, HARQ Type II (Chase combining) will be explained. Chase combining technique, according to which an original transmission and retransmissions are generally identical, can be applied to the data field of the physical protocol data unit (PPDU) in the physical (PHY) layer with the requirement that the retransmitted copy shall be exactly the same as the previously failed data field of the PPDU. As can be seen in FIG. 3 showing a diagram of a PPDU and its relation to a medium access control (MAC) protocol data unit (MPDU) and codeword(s), this implies that service field, MAC header, frame body, FCS and PHY padding are the same. It may happen that multiple MPDUs are aggregated in which case all MAC headers, frame bodies, FCS, and delimiters shall be unchanged and in the same order as in the original transmission. This cannot be achieved with today's WLAN as in the current WLAN, the failed MPDUs are retransmitted after the failure of the FCS (CRC) check from the MAC layer with some changes in the associated field. In particular, the code rate and modulation are generally varying depending on the setting in the PHY preamble so that HARQ soft combining happens in the data field part only.

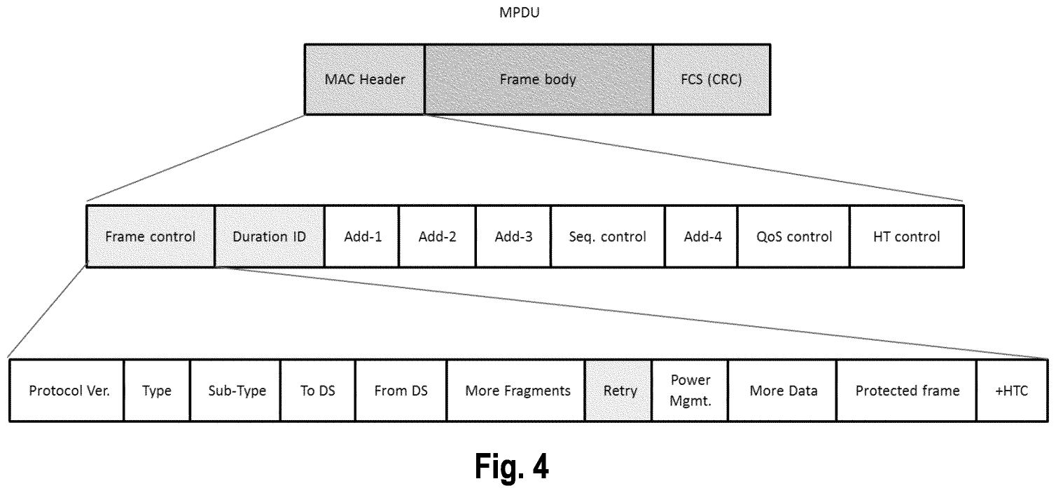

For example, the MAC header of the MPDU may comprise a Retry bit field, which is set to 1 (initially 0) if retransmission is made. The other field such as Duration ID may also change according to the NAV setting in retransmission. When a Retry bit and a Duration ID field (illustrated in FIG. 4 showing an embodiment of a MAC header of a MPDU) change, then the FCS field will also change accordingly.

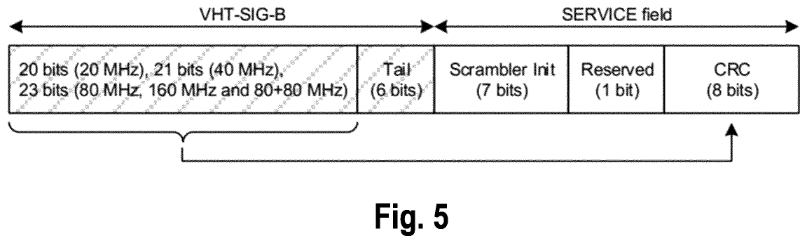

Similarly, in the PHY layer, for example in case of the VHT 802.11ac standard, the data field of a PHY protocol data unit (PPDU) consists of the service field whose last 8 bits are for CRC check generated for the VHT-SIG-B field from the PHY preamble. This is illustrated in FIG. 5 showing VHT-SIG-B and service field relationship. The VHT-SIG-B field may change if any content, for e.g. bandwidth, of it changes in retransmission that will lead to a different CRC in service field. For the HE 802.11ax and EHT 802.11be standards, a scrambler initialization should be the same for initial transmission and retransmissions.

Any change in these fields in the retransmission leads to a different data field of a PPDU than the previously transmitted data field. The data field of the PPDU is scrambled with a length-127 PPDU-synchronous scrambler in case of VHT 802.11ac/HE 802.11ax and with a length-2047 PPDU-synchronous scrambler in case of EHT 802.11be. The scrambled data is encoded to codewords as designated MCS.

During a retransmission, if the state of a scrambler is different compared to the initial transmission, then it will lead to different codewords. Hence, soft combining keeps the retransmitted data field and scrambler state the same as the previously transmitted one such that it leads to the same codeword.

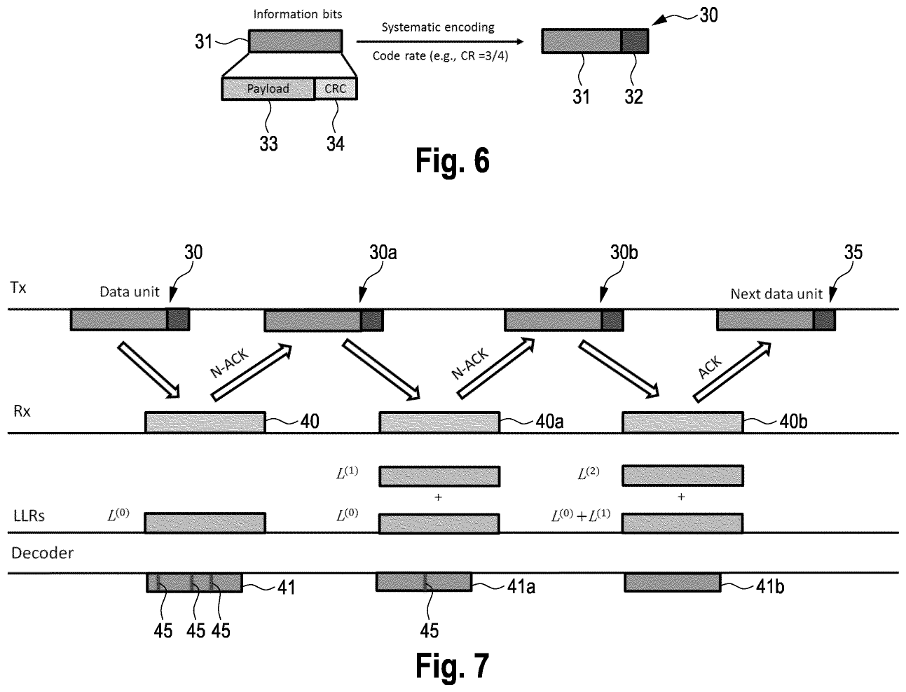

To apply Chase combining, the assumption can be made that an entire data field of a PPDU 31 as illustrated in FIG. 3 (in detail) and FIG. 6 (in short) is encoded to data unit 30 (codeword) which is transmitted. In general, the entire data field of a PPDU is encoded into multiple data units. The data unit 30 comprises an information part 31 and a parity part 32. The information part 31 comprises a payload part 33 and a CRC 34 (under the assumption that the entire data field of a PPDU fits into a single code word; otherwise, a codeword holds a fraction of the information part). The data unit 30 is generated from the information part 31 by systematic encoding using, as an example, a code rate CR=3/4), i.e., the parity part 32 is generated by encoding the data field of the PPDU 31.

In FIG. 6 the very special case that one MAC layer data unit (holding CRC) is encoded in one data unit/codeword is assumed. In general, a MAC layer data unit is encoded in multiple data units/codewords. This is e.g. illustrated in FIG. 3. Therefore, if an error is detected at the receiver using CRC, it can generally not be determined which data unit/codeword is wrong, but it is just known that at least one of it was erroneous.

Upon failure, the same entire data field is retransmitted under the constraints above. The entire data field shall be bit-wise equal. This implies that in a retransmission the scrambler seed is unchanged, i.e., the scrambler state is the same as the one used for the initial transmission, and all data units are the same and in the same order, which implies that length of each data unit, MAC header, delimiters (if present), and frame body is unchanged. The PHY header may be different and padding that does not have an impact on the encoding length may be different.

FIG. 7 schematically illustrates an embodiment of Chase combining scheme according to the present disclosure including two retransmissions. In other embodiment only one or more than two retransmissions may be made. The information bits 31 can be encoded into specific code rate codeword with the available LDPC matrix (e.g., CR=3/4) in WLAN. At the receiver, the erroneously received data unit 40 (indicated in FIG. 7 by error bits 45 in the respective information part 41 of the received data unit) is stored instead of discarding it. In response to a N-ACK, representing an indication indicating at least one erroneous data unit that failed to be received or decoded by the receiver, the transmitter retransmits the same data unit 30 again (in this case two times, indicated as data units 30a, 30b) leading to another erroneously received data unit 40a and a correctly received data unit 40b, which is confirmed by transmitting ACK to the transmitter. The transmitter will then send the next (different) data unit 35.

Since in Chase combining, all retransmitted data units are bit-wise identical to the initial transmitted data unit consisting of the same information, the receiver combines the log-likelihood ratio (LLR) values L (k) (where k is number of transmission or Tx count) of the same bits received in the initial transmission and the corresponding retransmissions, i.e. data units 40, 40a, 40b received from the transmissions of data units 30, 30a, 30b. Due to the time-varying channel, the receiver may take advantage of the channel variation in each retransmission, and combining all retransmitted versions of the same data unit will help in obtaining temporal diversity. This diversity gain due to channel variation may increase the likelihood of successful decoding at the receiver. Thus, according to the present disclosure, the LLRs of the erroneous data unit and the corresponding retransmission of the erroneous data unit are combined and the data unit is finally decoded based on the accumulated LLRs.

In current WLAN implementations, the retransmissions would have the same frame body of MAC data unit but different MAC header (different setting of retry bit). The encoding process into codewords (data units) would result in different information parts within the codewords (data units) which means that the codewords (data units) cannot be accumulated. According to the present disclosure the MAC data units are encoded into codewords (data units), so that each codeword is the same and contains the same part of a MAC data unit in the initial transmission and the corresponding retransmission.

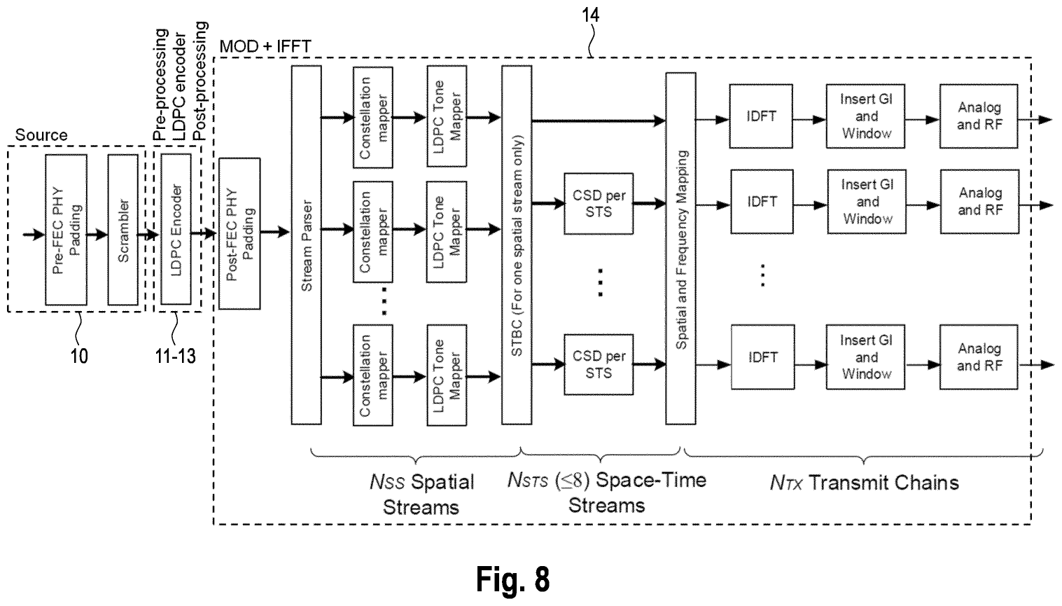

It shall be noted that for successful Chase combining, a PPDU may be different to such an extent that it does not affect decoding of the data units that are encoded. FIG. 8 schematically shows a WLAN PHY block diagram for processing the data field of a PPDU with LDPC encoding. It shows more details of the blocks of the transmitter side of the encoding and decoding scheme 1 shown in FIG. 2 and accordingly uses the same reference signs.

In principle, the parameters of any sub-block within the MOD+IFFT block 14 can potentially be changed for HARQ retransmission in comparison to the initial transmission. However, all sub-blocks of the source block 10 and the pre-processing, LDPC encoding and post-processing block 11-13 shall be unchanged.

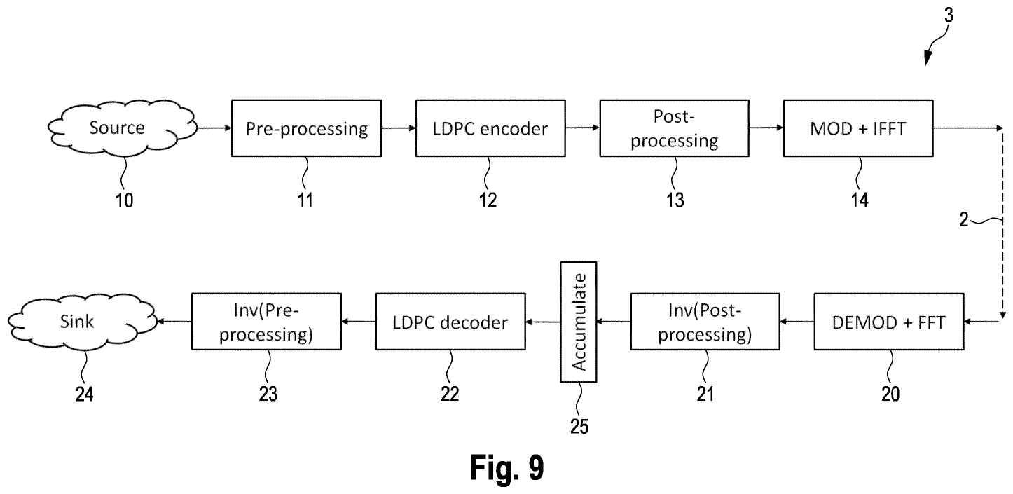

FIG. 9 shows a schematic diagram of the encoding and decoding scheme 3 for Chase combining according to an embodiment of the present disclosure. This scheme is similar to the known concept, as e.g. shown in FIG. 2, but additionally comprises an accumulate unit 25 at the receiver side to perform Chase combining. All the units except the accumulate unit 25 generally operate and function as described above for the known concept and as generally known.

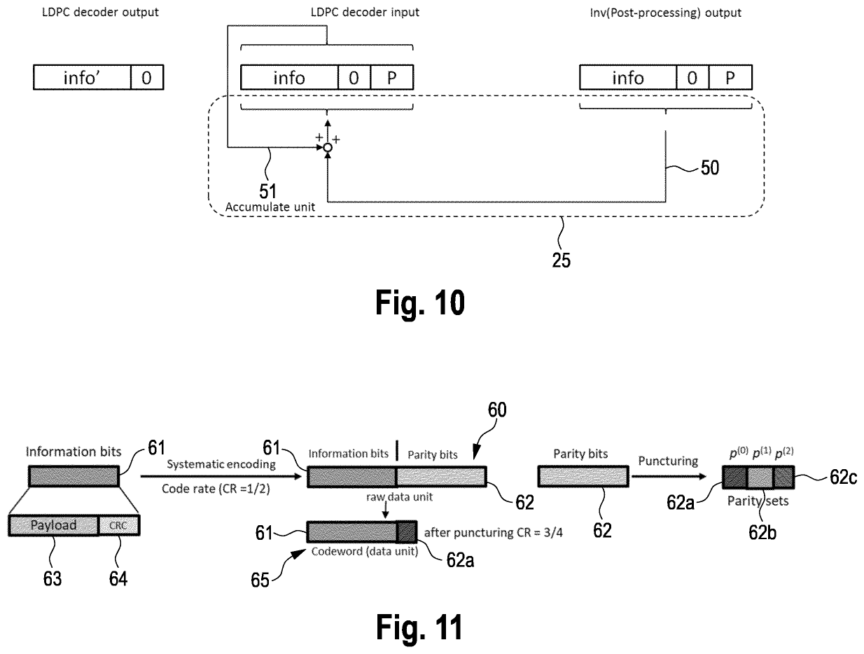

FIG. 10 shows a diagram illustrating an embodiment of the operation of the accumulate unit 25. LLR values 51 (i.e., the output of inverse post-processing unit 21) of the previously failed codeword are stored and combined with the LLR values 50 of a newly transmitted copy of the codeword. FIG. 10 illustrates the processing for a single codeword. However, a data field of PPDU is typically encoded to a number of multiple codewords in which case the same process repeats for all codewords independently. Thereby, the accumulation unit 25 generally combines related codewords, i.e., the first codeword (or data unit) of data field of PPDU is combined with the first codeword (or data unit) of an earlier received and equal (in the sense as explained above) data field of PPDU.

After combining LLR values of the same codewords from the initial transmission and one or more retransmissions, the combined soft output values are fed to the LDPC decoder 23 which takes the advantages of combination gain and increase of the likelihood of successful decoding. Finally, the output of the LDPC decoder 22 is inverse pre-processed in inverse pre-processing unit 23, and payload bits are retrieved at the receiver (sink 24).

In the following another embodiment of the present disclosure will be described, which is called HARQ Type III. This is another scheme of soft combining that includes both Chase combining and incremental redundancy technique. In this scheme, the systematic information bits of one or more codeword(s) are included in every transmission so that each transmission can be decoded independently of the previous transmissions. Generally, only parity bits are varied from one transmission to another. The systematic information part is Chase combined whereas new parity sets in each transmission provide incremental redundancy.

FIG. 11 shows a diagram of a PPDU 60 used according to HARQ Type III. Generally, the raw data unit 60 is generated in the same manner as encoding the data field of PPDU shown in FIG. 6, but with a different code rate (CR=1/2). The raw data unit 60 comprises a raw codeword having an information part 61 and a parity part 62. The information part 61 comprise a payload part 63 and a CRC 64. The raw data unit 60 is generated from the information part 61 by systematic encoding. The parity part 62 can be split into several (in this example three) parity portions (or sets) 62a, 62b, 62c (indicated as p⁽⁰⁾, p⁽¹⁾ and p⁽²⁾), e.g., by puncturing. A data unit (codeword) thus comprises the information part 61 and one of the parity portions 62a, 62b, 62c (in FIG. 11 the codeword 65a is shown comprising the information part 61 and the parity portion 62a).

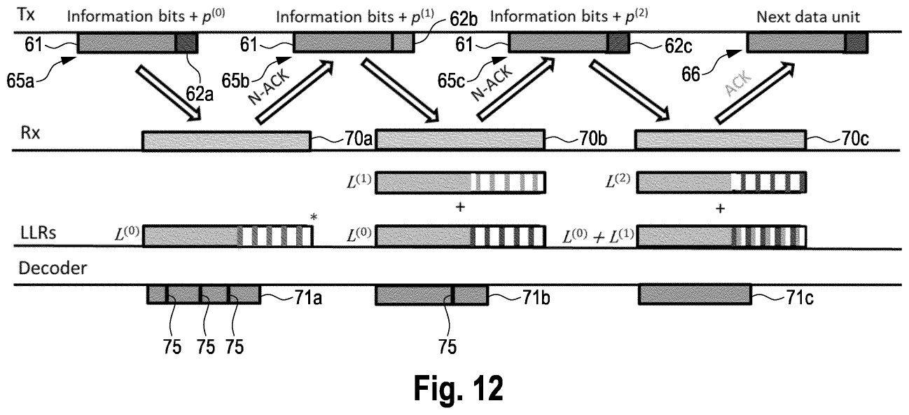

FIG. 12 schematically illustrates an embodiment of the HARQ Type III combining scheme according to the present disclosure, in this example with a maximum number of two retransmissions. In the initial transmission of the data unit 65a, the information part 61 with the first set of parity bits 62a (p⁽⁰⁾) is transmitted with a code rate (CR=3/4). Upon failure, in each retransmission of data units 65b, 65c, the information part 61 is sent with another (new) set of parity bits 62b (p⁽¹⁾) or 62c (p⁽²⁾).

The receiver receives data units 70a, 70b, 70c and provides feedback to the transmitter about the reception status of the data units in the form of N-Ack or Ack, as explained above with reference to FIG. 7. After confirmation of a correct reception or decoding, the transmitter will send the next (new) data unit 65. As shown in the last line, errors 75 appear in the information parts 71a, 71b of the first two received data units 70a, 70b. The information parts of the received data units 70a, 70b, 70c is Chase combined, and the parity bits of the different parity sets p⁽⁰⁾, p⁽¹⁾ and p⁽²⁾ are redistributed at their original location where they have been punctured. The receiver uses a CR=1/2 decoder and inserts at yet unknow parity positions a LLR value of 0, i.e., an uncertain bit (indicated by white lines in the LLR blocks).

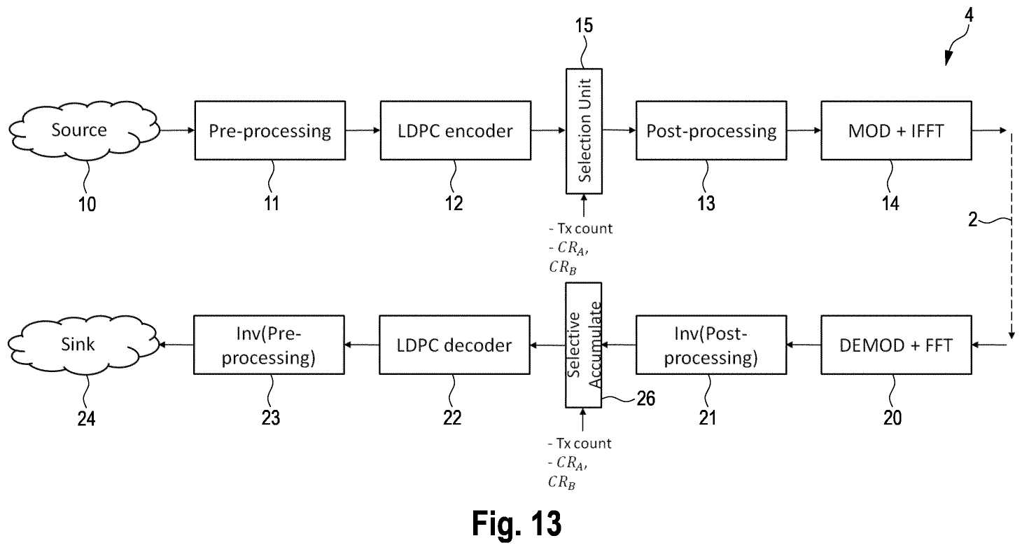

FIG. 13 shows a schematic diagram of the encoding and decoding scheme 4 for HARQ Type III combining according to an embodiment of the present disclosure. Compared to the encoding and decoding scheme 1 shown in FIG. 2 it comprises two additional units to implement both Chase combining and incremental redundancy operations. These additional units are a selection unit 15 at the transmitter side and a selective accumulate unit 26 at the receiver side. Along with these addition units, some functions of other units are also modified to make it compatible to apply HARQ Type III.

In the pre-processing unit 11, a higher code rate CR_{A} is predetermined by puncturing the codeword generated by LDPC matrix of code rate CR_{B}=1/2. For example, if three parity sets are formed as illustrated in FIG. 11, a code rate CR_{A}=3/4 may be used.

$${R}_{B} = \frac{1}{2} = \frac{1}{1 + 1} = \frac{3}{3 + 3}$$

which means three information bits, before encoding results in three information bits after encoding (systematic part) and three parity bits (parity part). If the parity part is divided in three sets, three information bits result in three info bits after encoding and one parity bit: hence

$${R}_{A} = \frac{3}{3 + 1} = 3 / 4.$$

The initial number of OFDM symbols and the codeword length may be determined as in the known system. However, the new codeword length may be set according to the punctured size. For example, if the codeword length 1944 is selected based on the scrambled bits coming from the source 10, then, at first, with code rate CR_{B}=1/2, it has 972 information bits and 972 parity bits. Second, to achieve higher code rate CR_{A}=3/4, the parity bits may be punctured and divided into three different parity sets. Out of three different parity sets, one parity set may be used, i.e 972/3=324 bits, and thus a new codeword length may be set to 1296 (972 information bits+324 parity bits). The LDPC encoder 12 runs at a rate CR_{B}≤CR_{A}.

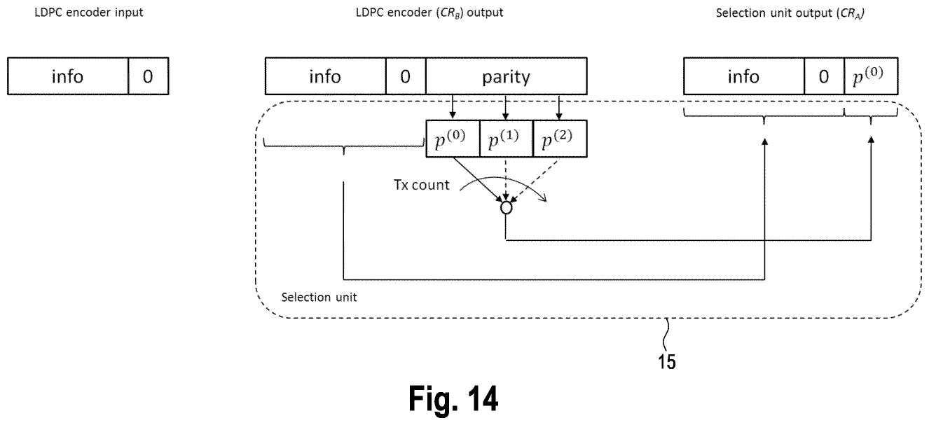

Subsequently, the selection unit 15, as shown in more detail in FIG. 14 for a single codeword, selects parity bits out of the parity part to get a higher code rate CR_{A}. The selected set of parities p⁽⁰⁾, p⁽¹⁾, and p⁽²⁾ depends on the number of transmissions, e.g., initial transmission or first retransmission etc. (Tx count). The parity set and/or the number of transmission should be known to the receiver such that it can perform adequate reverse operations. It is also preferred to have a unique (and/or standardized) mapping between the number of transmission and the selected parities.

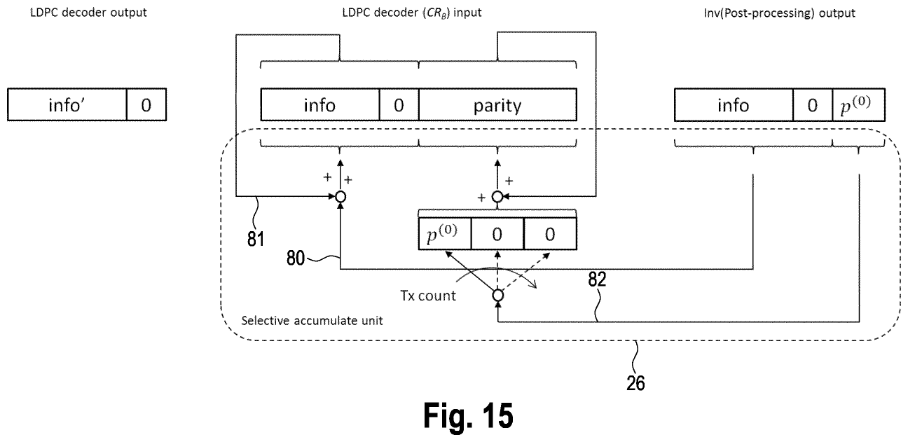

At the receiver side, after performing the reverse operation by the inverse post-processing unit 21, the soft output LLR values are forwarded to the selective accumulate unit 26. The operation of this unit is shown in FIG. 15 in more detail for a single codeword, but it is likewise applicable to multiple codewords. Here, the selective accumulate unit 26 Chase combines the same information parts 80, 81 of received codeword(s), and parity sets 82 are rearranged from where they have been punctured before as per number of Tx count. At the initial transmission and/or transmission count less than maximum retransmission where all parity sets are not available, zero LLR values are inserted in empty punctured locations to fill up the codeword length. The LDPC decoder 22 will decode with LDPC matrix code rate CR_{B}=1/2. Finally, the output of the LDPC decoder 22 is inverse pre-processed in unit 23 and payload bits are retrieved.

With the approach described above, the setting of CR_{A} and CR_{B} should preferably be identical for a particular data unit that is to be combined at the receiver, which means that both parameters do not change in between an initial transmission and a retransmission.

The following table gives an overview about settings CR_{A} and CR_{B} in dependency of the number of different parity sets to be provisioned. For table design, all CR_{B} of the WLAN standard have been considered.

| | CR_{A} | | | |
|---|---|---|---|---|
| CR_{B} | 2 parity sets | 3 parity sets | 4 parity sets | 5 parity sets |
| 1/2 | 2/3 | 3/4 | 4/5 | 5/6 |
| 2/3 | 4/5 | 6/7 | 8/9 | 10/11 |
| 3/4 | 6/7 | 9/10 | 12/13 | 15/16 |
| 5/6 | 10/11 | 15/16 | 20/21 | 25/26 |

As can be seen above, the receiver should be aware about what it can do in terms of HARQ soft combining. Such information may be provided by the transmitter in the PHY preamble.

Such information may includes one or more of the following (a subset of the following pieces of information may e.g. be sufficient if certain settings and/or configurations are standardized):
If the PPDU is soft-combinable and if yes, which method shall be applied (either Chase combining or HARQ Type III). Soft combinable means that the requirements mentioned above are fulfilled.
An identifier of the PPDU to which the current PPDU should be combined with. This can be implemented by a sequence number for example. PPDUs with same sequence number can be combined.
An identifier of the Tx count (for HARQ Type III only) so that the receiver is aware about parity insertion location.
If a mapping between Tx count and parity set does not exist, a signaling that defines that the parity set should be defined.
Code rate CR_{A} and CR_{B} or related information.
If CR_{A}≠CR_{B}, information about new code word length should be signaled too.

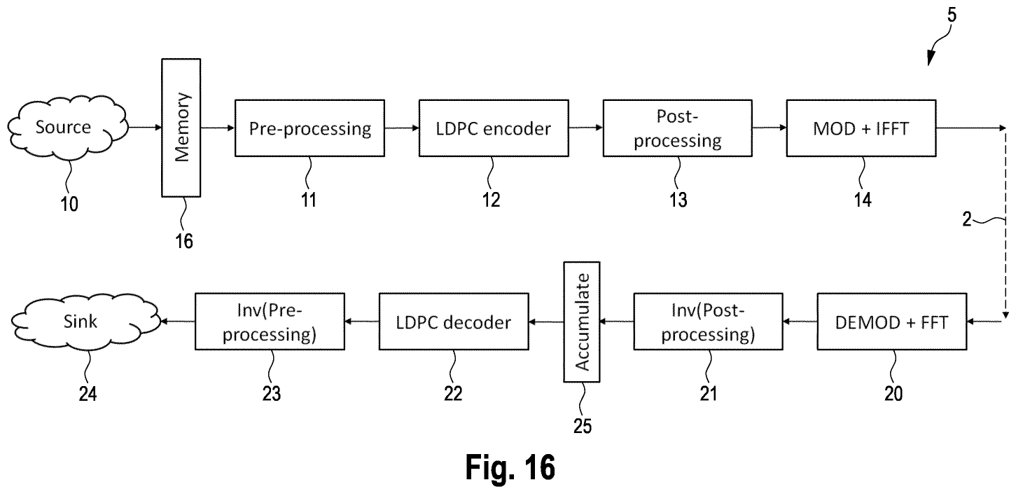

FIG. 16 shows a schematic diagram of the encoding and decoding scheme 5 for Chase combining according to another embodiment of the present disclosure. This scheme is similar to the concept shown in FIG. 9, but additionally comprises a memory unit 16 at the transmitter side. This memory unit 16 may store scrambled bits of a MAC layer data unit for a predetermined period or until an acknowledgement of correct decoding is received from the receiver. The memory unit 16 thus buffers data that come from the MAC layer so that content is unchanged. The memory unit 16 may be shifted to another place on the transmitter side, e.g. after the LDPC encoder 12. Using such a memory unit 16, the MAC layer is not involved in the retransmission, i.e., it does not set any retry subfield or duration/ID field to a different value. It shall be noted that the memory unit 16 may be used in the encoding and decoding scheme 4 shown in FIG. 13 as well.

Alternatively, in particular in the absence of such a memory unit 15, one or more MAC layer data units may need to be encoded again in case of reception of an indication from the receiver indicating at least one erroneous data unit that failed to be received or decoded by the receiver and to use the resulting data units for the retransmission.

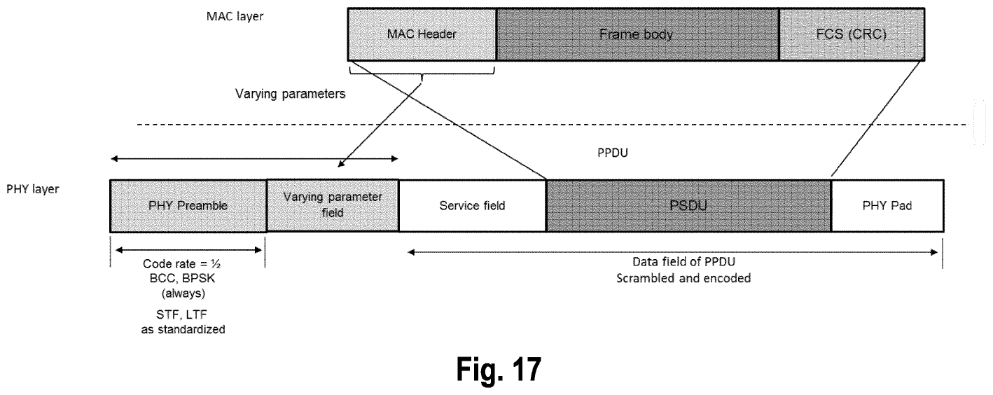

As explained above, the soft combining happens only in the data part of a PPDU. Therefore, the data part shall be unchanged, but the preamble may change. Some information of the MAC header may still be maintained, e.g. the retry subfield, because the receiver should know what to do with the received data unit. Further, duration subfield should be kept. Thus, information coming from the MAC layer may be split into two parts; A “combinable” part which does not change (which would be the “data field of PPDU”), and a “non-combinable” part which may change (which would be the “PHY Preamble”) wherein the PHY Preamble may include parts of MAC header that are subject to change, and which may be included into a varying parameter field. This is illustrated in FIG. 17 showing a diagram of another embodiment of a PPDU and its relation to a MPDU according to the present disclosure, according to which the PPDU additionally comprises a varying parameter field.

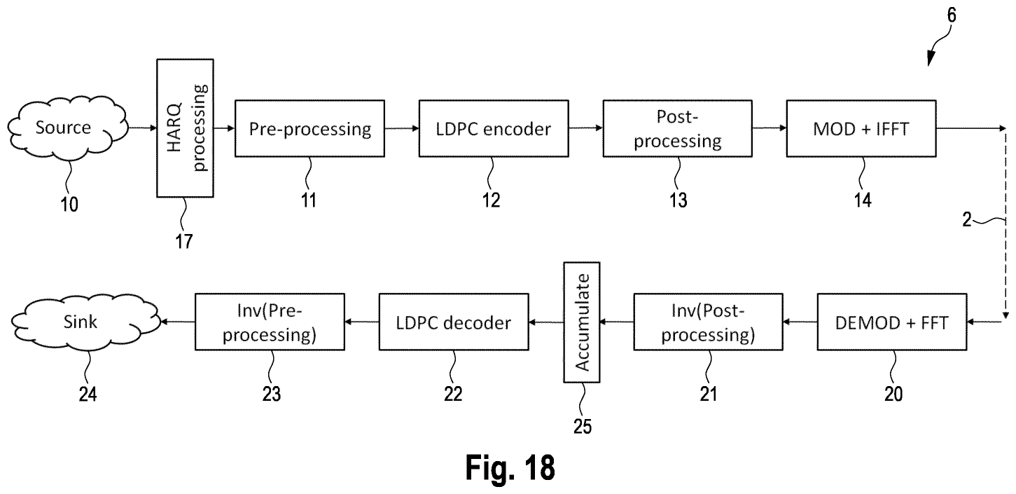

FIG. 18 shows a schematic diagram of the encoding and decoding scheme 6 for Chase combining according to still another embodiment of the present disclosure. This scheme is similar to the concept shown in FIG. 9, but additionally comprises a HARQ processing unit 17 at the transmitter side. This HARQ processing unit 17 performs a separation into the combinable and non-combinable part. If it has a memory, it has an input port for new MAC header information; if it has no memory, it extracts new MAC header information and then reverts the new information in MAC header to achieve the same combinable part as in the initial transmission. It shall be noted that the HARQ processing unit 17 may be used in the encoding and decoding scheme 4 shown in FIG. 13 as well.

In summary, hybrid ARQ with soft combining is one of the new features that can be applied in currently existing ARQ protocol in WLAN to increase the reliability of the communication. The soft combining techniques can be done either by HARQ Type II (Chase combining (CC) or incremental redundancy (IR)) or HARQ Type III (combination of CC and IR). The different methods of soft combining the erroneous data unit with the newly retransmitted copies or the information related to the initially transmitted data unit can promisingly increase the link reliability and robustness of the wireless communication and, hence, can increase the overall efficiency of the system. The disclosed CC and HARQ Type III soft combining techniques can e.g. be implemented in WLAN by modifying some of the parameters of LDPC encoding and decoding procedure and/or by adding new additional units.

Thus, the foregoing discussion discloses and describes merely exemplary embodiments of the present disclosure. As will be understood by those skilled in the art, the present disclosure may be embodied in other specific forms without departing from the spirit or essential characteristics thereof. Accordingly, the disclosure of the present disclosure is intended to be illustrative, but not limiting of the scope of the disclosure, as well as other claims. The disclosure, including any readily discernible variants of the teachings herein, defines, in part, the scope of the foregoing claim terminology such that no inventive subject matter is dedicated to the public.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measures cannot be used to advantage.

In so far as embodiments of the disclosure have been described as being implemented, at least in part, by software-controlled data processing apparatus, it will be appreciated that a non-transitory machine-readable medium carrying such software, such as an optical disk, a magnetic disk, semiconductor memory or the like, is also considered to represent an embodiment of the present disclosure. Further, such a software may also be distributed in other forms, such as via the Internet or other wired or wireless telecommunication systems.

The elements of the disclosed devices, apparatus and systems may be implemented by corresponding hardware and/or software elements, for instance appropriated circuits. A circuit is a structural assemblage of electronic components including conventional circuit elements, integrated circuits including application specific integrated circuits, standard integrated circuits, application specific standard products, and field programmable gate arrays. Further a circuit includes central processing units, graphics processing units, and microprocessors which are programmed or configured according to software code. A circuit does not include pure software, although a circuit includes the above-described hardware executing software.

It follows a list of further embodiments of the disclosed subject matter:

1. First communication device configured to communicate with a second communication device, the first communication device comprising circuitry configured to
receive data units, a received data unit comprising an information part and at least a portion of a parity part of a codeword comprising said information part and said parity part, from the second communication device;
provide an indication to the second communication device indicating at least one erroneous data unit that failed to be received or decoded by the first communication device;
receive a retransmission of the erroneous data unit having an identical information part as the corresponding originally transmitted data unit;
accumulate log-likelihood ratios (LLRs) of the erroneous data unit and the corresponding retransmission of the erroneous data unit; and
decode the data unit based on the accumulated LLRs.

2. First communication device according to embodiment 1,
wherein the circuitry is configured to evaluate a frame check sequence (FCS) of a MAC layer data unit to determine if at least one of the data units that contain said MAC layer data unit is erroneous.

3. First communication device according to any one of the preceding embodiments, wherein the circuitry is configured to provide the reception status of one or more MAC layer data units that are contained within the received data units in an acknowledgement transmitted to the second communication device.

4. First communication device according to any one of the preceding embodiments, wherein the circuitry is configured to provide, as indication, a non-acknowledgement or no acknowledgement at all within a predetermined time period to the second communication device.

5. First communication device according to any one of the preceding embodiments, wherein the circuitry is configured to
provide another indication to the second communication device indicating that the erroneous data unit could not be decoded correctly by the first communication device based on the accumulated LLRs;
receive another retransmission of the erroneous data unit having an identical information part as the corresponding originally transmitted data unit;
accumulate LLRs of the erroneous data unit and the corresponding retransmissions; and
decode the data unit based on the accumulated LLRs.

6. First communication device according to any one of the preceding embodiments, wherein the circuitry is configured to accumulate the LLRs of the erroneous data unit and corresponding one or more retransmissions by bitwise adding the LLRs.

7. First communication device according to any one of the preceding embodiments, wherein the circuitry is configured to store LLRs of an erroneous data unit and corresponding one or more retransmissions until one or more of:
a predetermined number of retransmissions have been received;
the data unit could be correctly decoded based on the accumulated LLRs;
lifetime of said data unit is exceeded;
a request to discard said LLRs of an erroneous data unit is received from the second communication device.

8. First communication device according to any one of the preceding embodiments, wherein the circuitry is configured to
receive a transmitted data unit including, in addition to an identical information part as the corresponding originally transmitted data unit, a first portion of the parity part;
receive one or more retransmissions of the corresponding erroneous data unit, each including, in addition to the identical information part as the corresponding originally transmitted data unit, a further portion of the parity part instead of the first portion of the parity part; and
decode the data unit based on, in addition to the accumulated LLRs, the received first portion and one or more further portions of the parity part received with one or more retransmissions.

9. First communication device according to embodiment 8,
wherein the circuitry is configured to use the LLRs of the received parity portions of the parity part for decoding the data unit.

10. First communication device according to embodiment 9, wherein the circuitry is configured to set the LLR of one or more not received parity portions of the parity part of a data unit to zero.

11. First communication device according to any one of the preceding embodiments, wherein the circuitry is configured to
assemble raw data units by accumulating the LLRs of the information part of the originally transmitted data unit and corresponding one or more retransmissions and by accumulating and/or arranging the portion of LLRs of the parity part of the originally transmitted data unit and corresponding one or more retransmissions at appropriate location, and
decode said raw data unit with a systematic decoder to obtain one or more MAC layer data units.

12. First communication device according to any one of the preceding embodiments, wherein the circuitry is configured to decode a data unit using decoding information received from the second communication device, the decoding information indicating one or more of:
if soft combining can be applied;
the type of soft combining;
the originally transmitted data unit which corresponds to a retransmitted data unit;
a location within the parity part at which a transmitted parity portion shall be inserted;
a code rate of the transmitted or retransmitted data unit;
a code rate of the raw data units; and
a length of the transmitted or retransmitted data unit.

13. Second communication device configured to communicate with a first communication device, the second communication device comprising circuitry configured to
transmit data units, a transmitted data unit comprising an information part and at least a portion of a parity part, to the first communication device;
obtain an indication from the first communication device indicating at least one erroneous data unit that failed to be received or decoded by the first communication device; and
retransmit the erroneous data unit having at least an identical information part as the corresponding originally transmitted data unit.

14. Second communication device according to embodiment 13, wherein the circuitry is configured to
transmit data units, containing one or more MAC layer data units; and
include the reception status of the one or more MAC layer data units in an acknowledgement received from the first communication device.

15. Second communication device according to any one of embodiments 13 to 14, wherein the circuitry is configured to include in the retransmitted data unit the same one or more medium access control (MAC) layer data as included in the corresponding originally transmitted data unit.

16. Second communication device according to embodiment 15, wherein the circuitry is configured to include in the retransmitted data unit the same MAC header, frame body and frame check sequence (FCS) as included in the corresponding originally transmitted data unit.

17. Second communication device according to embodiment 15 or 16, wherein the circuitry is configured to further include in the retransmitted data unit the same service field and, if included, the same physical layer (PHY) padding field and the same zero or more delimiters as included in the corresponding originally transmitted data unit.

18. Second communication device according to any one of embodiments 13 to 17, wherein the circuitry is configured to include, in a transmitted or a corresponding retransmitted data unit, the same parity part or the complete parity part.

19. Second communication device according to any one of embodiments 13 to 18, wherein the circuitry is configured to create data units by encoding one or more MAC layer data units with a systematic code.

20. Second communication device according to any one of embodiments 13 to 19, wherein the circuitry is configured to include, in a transmitted or a corresponding retransmitted data unit, only a portion of the parity part, wherein the portion of the parity part is different for each retransmission, or the portion of the parity part increases for each retransmission.

21. Second communication device according to any one of embodiments 13 to 20, wherein the circuitry is configured to encode one or more MAC layer data units with a systematic code to obtain raw data units and to select only a portion of the parity part of said raw data units to create the data units comprising the same information part as the raw data units and the selected portion of the parity part.

22. Second communication device according to any one of embodiments 13 to 21, wherein the circuitry is configured to store a data unit for a predetermined period or until an acknowledgement of correct decoding is received from the first communication device.

23. Second communication device according to any one of embodiments 13 to 22, wherein the circuitry is configured to encode one or more MAC layer data units again in case of reception of an indication indicating at least one erroneous data unit that failed to be received or decoded by the first communication device and to use the resulting data units for the retransmission, wherein the one or more MAC layer data units are same as encoded in the original transmission.

24. Second communication device according to embodiment 23, wherein the circuitry is configured to use a same code rate for encoding the data unit again as for the original encoding of the data unit for the original transmission.

25. Second communication device according to embodiment 23 or 24, wherein the circuitry is configured to transmit to the first communication device included in or along with a transmitted or retransmitted data unit decoding information indicating one or more of:
if soft combining can be applied;
the type of soft combining;
the originally transmitted data unit which correspond to a retransmitted data unit;
a location within the parity part at which a transmitted parity portion shall be inserted;
a code rate of the transmitted data units;
a code rate of the raw data units; and
a length of the transmitted or retransmitted data unit.

26. First communication method of a first communication device configured to communicate with a second communication device, the first communication method comprising:
receiving data units, a received data unit comprising an information part and at least a portion of a parity part of a codeword comprising said information part and said parity part, from the second communication device;
providing an indication to the second communication device indicating at least one erroneous data unit that failed to be received or decoded by the first communication device;
receiving a retransmission of the erroneous data unit having an identical information part as the corresponding originally transmitted data unit;
accumulating log-likelihood ratios (LLRs) of the erroneous data unit and the corresponding retransmission of the erroneous data unit; and
decoding the data unit based on the accumulated LLRs.

27. Second communication method of a second communication device configured to communicate with a first communication device, the second communication method comprising:
transmitting data units, a transmitted data unit comprising an information part and at least a portion of a parity part, to the first communication device;
obtaining an indication from the first communication device indicating at least one erroneous data unit that failed to be received or decoded by the first communication device; and
retransmitting the erroneous data unit having at least an identical information part as the corresponding originally transmitted data unit.

28. A non-transitory computer-readable recording medium that stores therein a computer program product, which, when executed by a processor, causes the method according to embodiment 26 or 27 to be performed

29. A computer program comprising program code means for causing a computer to perform the steps of said method according to embodiment 26 or 27 when said computer pro-gram is carried out on a computer.

1. First communication device configured to communicate with a second communication device, the first communication device comprising circuitry configured to
receive data units, a received data unit comprising an information part and at least a portion of a parity part of a codeword comprising said information part and said parity part, from the second communication device;
provide an indication to the second communication device indicating at least one erroneous data unit that failed to be received or decoded by the first communication device;
receive a retransmission of the erroneous data unit having an identical information part as the corresponding originally transmitted data unit;
accumulate log-likelihood ratios (LLRs) of the erroneous data unit and the corresponding retransmission of the erroneous data unit; and
decode the data unit based on the accumulated LLRs.

2. First communication device according to claim 1,
wherein the circuitry is configured to evaluate a frame check sequence (FCS) of a MAC layer data unit to determine if at least one of the data units that contain said MAC layer data unit is erroneous.

3. First communication device according to claim 1,
wherein the circuitry is configured to provide the reception status of one or more MAC layer data units that are contained within the received data units in an acknowledgement transmitted to the second communication device and/or to provide, as indication, a non-acknowledgement or no acknowledgement at all within a predetermined time period to the second communication device.

4. First communication device according to claim 1,
wherein the circuitry is configured to
provide another indication to the second communication device indicating that the erroneous data unit could not be decoded correctly by the first communication device based on the accumulated LLRs;
receive another retransmission of the erroneous data unit having an identical information part as the corresponding originally transmitted data unit;
accumulate LLRs of the erroneous data unit and the corresponding retransmissions; and
decode the data unit based on the accumulated LLRs.

5. First communication device according to claim 1,
wherein the circuitry is configured to accumulate the LLRs of the erroneous data unit and corresponding one or more retransmissions by bitwise adding the LLRs.

6. First communication device according to claim 1,
wherein the circuitry is configured to store LLRs of an erroneous data unit and corresponding one or more retransmissions until one or more of:
a predetermined number of retransmissions have been received;
the data unit could be correctly decoded based on the accumulated LLRs;
lifetime of said data unit is exceeded;
a request to discard said LLRs of an erroneous data unit is received from the second communication device.

7. First communication device according to claim 1,
wherein the circuitry is configured to
receive a transmitted data unit including, in addition to an identical information part as the corresponding originally transmitted data unit, a first portion of the parity part;
receive one or more retransmissions of the corresponding erroneous data unit, each including, in addition to the identical information part as the corresponding originally transmitted data unit, a further portion of the parity part instead of the first portion of the parity part; and
decode the data unit based on, in addition to the accumulated LLRs, the received first portion and one or more further portions of the parity part received with one or more retransmissions.

8. First communication device according to claim 7,
wherein the circuitry is configured to use the LLRs of the received parity portions of the parity part for decoding the data unit, in particular to set the LLR of one or more not received parity portions of the parity part of a data unit to zero.

9. First communication device according to claim 1,
wherein the circuitry is configured to
assemble raw data units by accumulating the LLRs of the information part of the originally transmitted data unit and corresponding one or more retransmissions and by accumulating and/or arranging the portion of LLRs of the parity part of the originally transmitted data unit and corresponding one or more retransmissions at appropriate location, and
decode said raw data unit with a systematic decoder to obtain one or more MAC layer data units.

10. Second communication device configured to communicate with a first communication device, the second communication device comprising circuitry configured to
transmit data units, a transmitted data unit comprising an information part and at least a portion of a parity part, to the first communication device;
obtain an indication from the first communication device indicating at least one erroneous data unit that failed to be received or decoded by the first communication device; and
retransmit the erroneous data unit having at least an identical information part as the corresponding originally transmitted data unit.

11. Second communication device according to claim 10,
wherein the circuitry is configured to
transmit data units, containing one or more MAC layer data units; and
include the reception status of the one or more MAC layer data units in an acknowledgement received from the first communication device.

12. Second communication device according to claim 10,
wherein the circuitry is configured to include in the retransmitted data unit the same one or more medium access control (MAC) layer data as included in the corresponding originally transmitted data unit, in particular to include in the retransmitted data unit the same MAC header, frame body and frame check sequence (FCS) as included in the corresponding originally transmitted data unit and/or to further include in the retransmitted data unit the same service field and, if included, the same physical layer (PHY) padding field and the same zero or more delimiters as included in the corresponding originally transmitted data unit.

13. Second communication device according to claim 10,
wherein the circuitry is configured to include, in a transmitted or a corresponding retransmitted data unit, the same parity part or the complete parity part, and/or to include, in a transmitted or a corresponding retransmitted data unit, only a portion of the parity part, wherein the portion of the parity part is different for each retransmission, or the portion of the parity part increases for each retransmission.

14. Second communication device according to claim 10,
wherein the circuitry is configured
to create data units by encoding one or more MAC layer data units with a systematic code, and/or
to encode one or more MAC layer data units with a systematic code to obtain raw data units and to select only a portion of the parity part of said raw data units to create the data units comprising the same information part as the raw data units and the selected portion of the parity part.

15. Second communication device according to claim 10,
wherein the circuitry is configured to store a data unit for a predetermined period or until an acknowledgement of correct decoding is received from the first communication device.

16. Second communication device according to claim 10,
wherein the circuitry is configured to encode one or more MAC layer data units again in case of reception of an indication indicating at least one erroneous data unit that failed to be received or decoded by the first communication device, in particular using a same code rate for encoding the data unit again as for the original encoding of the data unit for the original transmission, and to use the resulting data units for the retransmission,
wherein the one or more MAC layer data units are same as encoded in the original transmission.

17. Second communication device according to claim 16,
wherein the circuitry is configured to transmit to the first communication device included in or along with a transmitted or retransmitted data unit decoding information indicating one or more of:
if soft combining can be applied;
the type of soft combining;
the originally transmitted data unit which correspond to a retransmitted data unit;
a location within the parity part at which a transmitted parity portion shall be inserted;
a code rate of the transmitted data units;
a code rate of the raw data units; and
a length of the transmitted or retransmitted data unit.

18. First communication method of a first communication device configured to communicate with a second communication device, the first communication method comprising:
receiving data units, a received data unit comprising an information part and at least a portion of a parity part of a codeword comprising said information part and said parity part, from the second communication device;
providing an indication to the second communication device indicating at least one erroneous data unit that failed to be received or decoded by the first communication device;
receiving a retransmission of the erroneous data unit having an identical information part as the corresponding originally transmitted data unit;
accumulating log-likelihood ratios (LLRs) of the erroneous data unit and the corresponding retransmission of the erroneous data unit; and
decoding the data unit based on the accumulated LLRs.

19. Second communication method of a second communication device configured to communicate with a first communication device, the second communication method comprising:
transmitting data units, a transmitted data unit comprising an information part and at least a portion of a parity part, to the first communication device;
obtaining an indication from the first communication device indicating at least one erroneous data unit that failed to be received or decoded by the first communication device; and
retransmitting the erroneous data unit having at least an identical information part as the corresponding originally transmitted data unit.

20. A non-transitory computer-readable recording medium that stores therein a computer program product, which, when executed by a processor, causes the method according to claim 18 or 19 to be performed.
